(19) United States
(12) Patent Application Publication
(10) Pub. No.: US 2023/0238407 A1
(43) Pub. Date: Jul. 27, 2023

(54) SOLID-STATE IMAGING DEVICE, METHOD OF MANUFACTURING THE SAME, AND ELECTRONIC DEVICE

(71) Applicant: SONY SEMICONDUCTOR SOLUTIONS CORPORATION, KANAGAWA (JP)

(72) Inventor: KEISUKE HATANO, KANAGAWA (JP)

(21) Appl. No.: 18/001,857

(22) PCT Filed: Jun. 8, 2021
(86) PCT No.: PCT/JP2021/021662

§ 371 Date: Dec. 14, 2022

(30) Foreign Application Priority Data
Jun. 22, 2020 (JP) 2020-106971

(51) Int. Cl. H01L 27/146

(52) U.S. Cl. CPC H01L 27/14618; H01L 27/14627; H01L 27/14636; H01L 27/14683

(57) ABSTRACT

The present technology relates to a solid-state imaging device capable of suppressing flare in a CSP-type solid-state imaging device having a cavityless structure, a method of manufacturing the same, and an electronic device. The solid-state imaging device includes: a semiconductor substrate in which a photoelectric conversion section is formed for each pixel; an on-chip lens formed on a light incident surface side of the semiconductor substrate; a light-transmissive substrate that protects the on-chip lens; and a bonding resin that bonds the light-transmissive substrate and the on-chip lens together. A first surface on the light incident surface side of the light-transmissive substrate is flat, and a second surface opposite to the first surface of the light-transmissive substrate has different thicknesses in a central region facing a pixel region of the semiconductor substrate and an outer peripheral region outside the central region. The present technology can be applied to, for example, a CSP-type solid-state imaging device having a cavityless structure or the like.

### TECHNICAL FIELD

The present technology relates to a solid-state imaging device, a method of manufacturing the same, and an electronic device, and more particularly, to a solid-state imaging device capable of suppressing flare, a method of manufacturing the same, and an electronic device.

### BACKGROUND ART

In response to a demand for downsizing a semiconductor device, there is a chip size package (CSP) in which the semiconductor device is downsized to a chip size.

In a CSP of a solid-state imaging device, in order to seal a pixel region in which a plurality of pixels is disposed, as a structure for bonding a glass substrate to a semiconductor substrate, there are a cavity structure in which a gap is provided between the semiconductor substrate and the glass substrate and a cavityless structure in which no gap is provided (see, for example, Patent Document 1).

For example, in a CSP-type solid-state imaging device having a cavity structure, high-order light of diffracted light reflected by the front surface of the semiconductor substrate and incident on the glass substrate is totally reflected by the front surface (upper surface) of the glass substrate, and then totally reflected by the back surface (lower surface) of the glass substrate. As a result, high-order light of diffracted light is prevented from returning to the pixel region.

### CITATION LIST

### Patent Document

Patent Literature 1: WO 2017/163924 A

### SUMMARY OF THE INVENTION

### Problems to be Solved by the Invention

On the other hand, in the CSP-type solid-state imaging device having the cavityless structure, high-order light of diffracted light reflected by the front surface of the semiconductor substrate and incident on the glass substrate may return to the pixel region without being totally reflected by the back surface after being totally reflected by the front surface of the glass substrate. That is, in the cavityless structure, since the space between the semiconductor substrate and the glass substrate is filled with the resin having the same refractive index as the glass substrate without any gap, the reflected light totally reflected by the upper surface of the glass substrate does not reflect at the interface between the glass substrate and the resin, but returns to the pixel region of the semiconductor substrate as it is, and high-order light of the diffracted light may become a ring-shaped flare and adversely affect image quality.

The present technology has been made in view of such a situation, and an object thereof is to suppress flare in a CSP-type solid-state imaging device having a cavityless structure.

### Solutions to Problems

A solid-state imaging device according to a first aspect of the present technology includes:

a semiconductor substrate in which a photoelectric conversion section is formed for a pixel;

an on-chip lens formed on a light incident surface side of the semiconductor substrate;

a light-transmissive substrate that protects the on-chip lens; and

a bonding resin that bonds the light-transmissive substrate and the on-chip lens together,

in which a first surface on a light incident surface side of the light-transmissive substrate is flat, and

a second surface opposite to the first surface of the light-transmissive substrate has different thicknesses in a central region facing a pixel region of the semiconductor substrate and an outer peripheral region outside the central region.

In a method of manufacturing a solid-state imaging device according to a second aspect of the present technology, the solid-state imaging device includes:

a semiconductor substrate in which a photoelectric conversion section is formed for a pixel;

an on-chip lens formed on a light incident surface side of the semiconductor substrate; and

a light-transmissive substrate that protects the on-chip lens,

in which a first surface on a light incident surface side of the light-transmissive substrate is flat,

a second surface opposite to the first surface of the light-transmissive substrate has different thicknesses in a central region facing a pixel region of the semiconductor substrate and an outer peripheral region outside the central region, and

the light-transmissive substrate and the on-chip lens are bonded together with a bonding resin.

An electronic device according to a third aspect of the present technology includes a solid-state imaging device including:

a semiconductor substrate in which a photoelectric conversion section is formed for a pixel;

an on-chip lens formed on a light incident surface side of the semiconductor substrate;

a light-transmissive substrate that protects the on-chip lens; and

a bonding resin that bonds the light-transmissive substrate and the on-chip lens together,

in which a first surface on a light incident surface side of the light-transmissive substrate is flat, and

a second surface opposite to the first surface of the light-transmissive substrate has different thicknesses in a central region facing a pixel region of the semiconductor substrate and an outer peripheral region outside the central region.

In the first to third aspects of the present technology, provided are: a semiconductor substrate in which a photoelectric conversion section is formed for a pixel; an on-chip lens formed on a light incident surface side of the semiconductor substrate; a light-transmissive substrate that protects the on-chip lens; and a bonding resin that bonds the light-transmissive substrate and the on-chip lens together, in which a first surface on a light incident surface side of the light-transmissive substrate is flat, and a second surface opposite to the first surface of the light-transmissive substrate has different thicknesses in a central region facing a pixel region of the semiconductor substrate and an outer peripheral region outside the central region.

The solid-state imaging device and the electronic device may be independent devices or modules incorporated in other devices.

### BRIEF DESCRIPTION OF DRAWINGS

FIG. 1 is a cross-sectional view illustrating a configuration example of a first embodiment of a solid-state imaging device to which the present technology is applied.

FIG. 2 is a plan view of a light-transmissive substrate of FIG. 1.

FIG. 3 is a perspective view illustrating a configuration example of each of a lower substrate and an upper substrate.

FIG. 4 is a diagram illustrating a circuit configuration example of the solid-state imaging device.

FIG. 5 is a diagram illustrating a circuit configuration example of a pixel.

FIG. 6 is a diagram for explaining a problem of the cavityless structure.

FIG. 7 is a cross-sectional view of the vicinity of an end portion of the solid-state imaging device in FIG. 1.

FIG. 8 is a cross-sectional view of the vicinity of an end portion in a case where there is an OPB region.

FIG. 9 is a diagram for explaining a method of manufacturing the solid-state imaging device in FIG. 1.

FIG. 10 is a diagram for explaining a method of manufacturing the solid-state imaging device in FIG. 1.

FIG. 11 is a diagram for explaining a method of manufacturing the solid-state imaging device in FIG. 1.

FIG. 12 is a diagram for explaining a method of manufacturing the solid-state imaging device in FIG. 1.

FIG. 13 is a diagram for explaining a method of manufacturing the solid-state imaging device in FIG. 1.

FIG. 14 is a plan view of a light-transmissive substrate in a wafer state.

FIG. 15 is a view illustrating another first shape example of the light-transmissive substrate.

FIG. 16 is a plan view of the light-transmissive substrate in a wafer state in FIG. 15.

FIG. 17 is a view illustrating another second shape example of the light-transmissive substrate.

FIG. 18 is a plan view of the light-transmissive substrate in a wafer state in FIG. 17.

FIG. 19 is a cross-sectional view illustrating a configuration example of a second embodiment of a solid-state imaging device to which the present technology is applied.

FIG. 20 is a cross-sectional view illustrating a configuration example of a third embodiment of a solid-state imaging device to which the present technology is applied.

FIG. 21 is a cross-sectional view illustrating a configuration example of a fourth embodiment of a solid-state imaging device to which the present technology is applied.

FIG. 22 is a cross-sectional view illustrating a configuration example of a fifth embodiment of a solid-state imaging device to which the present technology is applied.

FIG. 23 is a cross-sectional view of the vicinity of an end portion in the case of including a color filter layer.

FIG. 24 is a diagram for explaining a usage example of an image sensor.

FIG. 25 is a block diagram illustrating a configuration example of an imaging device as an electronic device to which the present technology is applied.

FIG. 26 is a view depicting an example of a schematic configuration of an endoscopic surgery system.

FIG. 27 is a block diagram depicting an example of a functional configuration of a camera head and a camera control unit (CCU).

FIG. 28 is a block diagram depicting an example of schematic configuration of a vehicle control system.

FIG. 29 is a diagram of assistance in explaining an example of installation positions of an outside-vehicle information detecting section and an imaging section.

### MODE FOR CARRYING OUT THE INVENTION

Modes for carrying out the present technology (hereinafter, referred to as embodiments) will be described below. Note that the description will be given in the following order.

1. First Embodiment of Solid-State Imaging Device

2. Circuit Configuration Example of Solid-State Imaging Device

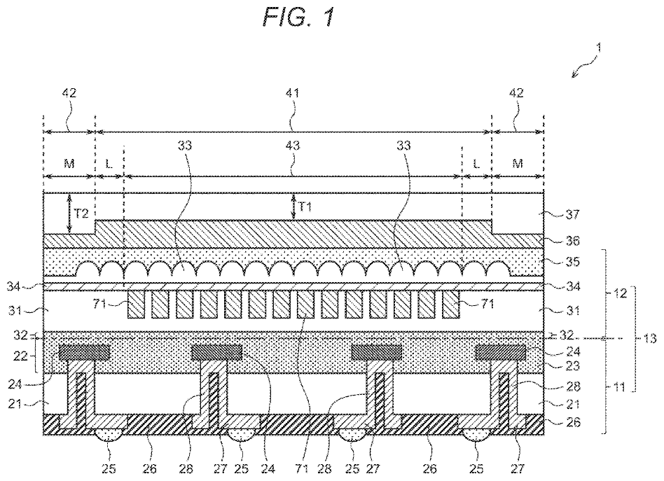

3. Effects of Device Structure in FIG. 1

4. Derivation of Distance L

5. Method of Manufacturing Solid-State Imaging Device

6. Other Shape Examples of Light-Transmissive Substrate

7. Second Embodiment of Solid-State Imaging Device

8. Third Embodiment of Solid-State Imaging Device

9. Fourth Embodiment of Solid-State Imaging Device

10. Fifth Embodiment of Solid-State Imaging Device

11. Configuration Example Including Color Filter Layer

12. Usage Example of Image Sensor

13. Application Example to Electronic Device

14. Application Example to Endoscopic Surgery System

15. Application Example to Mobile Body

Note that, in the drawings referred to in the following description, the same or similar parts are denoted by the same or similar reference numerals. However, the drawings are schematic, and the relationship between the thickness and the plane dimension, the ratio of the thickness of each layer, and the like are different from the actual ones. In addition, the drawings may include portions having different dimensional relationships and ratios.

In addition, the definitions of directions such as up and down or the like in the following description are merely definitions for convenience of description, and do not limit the technical idea of the present disclosure. For example, when an object is observed by rotating the object by 90°, the up and down are converted into and read as left and right, and when the object is observed by rotating the object by 180°, the up and down are inverted and read.

<1. First Embodiment of Solid-State Imaging Device>

FIG. 1 is a cross-sectional view illustrating a configuration example of a first embodiment of a solid-state imaging device to which the present technology is applied.

A solid-state imaging device 1 illustrated in FIG. 1 is a semiconductor package in which a laminated substrate 13 configured by laminating a lower substrate 11 and an upper substrate 12 is packaged. The lower substrate 11 and the upper substrate 12 are bonded on a surface indicated by an alternate long and short dash line.

In the lower substrate 11, a multilayer wiring layer 22 is formed on the upper side (upper substrate 12 side) of a semiconductor substrate 21 (hereinafter, referred to as a silicon substrate 21) constituted by, for example, silicon (Si). The multilayer wiring layer 22 includes a plurality of wiring layers (not illustrated) and interlayer insulating films 23 therebetween.

On the back surface side opposite to the front surface side of the lower substrate 11 on which the multilayer wiring layer 22 is formed, a plurality of solder bumps 25, which are back electrodes for electrical connection with an external module substrate, is formed. A region other than the solder bumps 25 on the back surface side of the lower substrate 11 is covered with a protective film 26. As a material of the protective film 26, for example, a solder resist which is an organic material is used.

The solder bumps 25 are formed on rewiring lines 27 formed on the upper surface of the back side of the silicon substrate 21, and the rewiring lines 27 are electrically connected to internal electrodes 24 which are parts of the wiring layer of the multilayer wiring layer 22 on the front surface side via connection conductors 28 penetrating the silicon substrate 21. The rewiring lines 27 and the connection conductors 28 can be formed by, for example, copper (Cu), tungsten (W), titanium (Ti), tantalum (Ta), titanium tungsten alloy (TiW), polysilicon, or the like. Note that, although not illustrated, the rewiring lines 27 and the connection conductors 28 are insulated from the silicon substrate 21 by an insulating film.

Meanwhile, the upper substrate 12 includes a semiconductor substrate 31 (hereinafter, referred to as a silicon substrate 31) constituted by, for example, silicon (Si), a wiring layer 32 formed on one surface of the silicon substrate 31, and on-chip lenses 33 formed on the other surface.

In the silicon substrate 31, photodiodes 71 as photoelectric conversion sections are formed in units of pixels, and the on-chip lenses 33 are also formed in units of pixels corresponding to the photodiodes 71. In order to prevent lens shape collapse at the end portion of a pixel region 43, the on-chip lenses 33 are formed up to the outer side of the pixel region 43 so as to maintain pattern continuity at the end portion of the pixel region 43.

The wiring layer 32 formed on the front surface of the silicon substrate 31 includes, for example, a metal film such as copper (Cu), aluminum (Al), tungsten (W), or the like, and an interlayer insulating film such as a silicon oxide film, a silicon nitride film, or the like, and is electrically connected to the multilayer wiring layer 22 of the lower substrate 11 on a surface indicated by an alternate long and short dash line by metal bonding such as Cu-CU bonding or the like.

The on-chip lenses 33 formed on the back surface of the silicon substrate 31 are formed on the upper side of a planarization film 34 formed on the upper surface of the silicon substrate 31, and the upper side of the on-chip lenses 33 are formed flat by an interlayer insulating film 35. The interlayer insulating film 35 is formed by a material having a refractive index lower than that of the material of the on-chip lenses 33, and a refractive index difference is provided between the on-chip lenses 33 and the interlayer insulating film 35 thereon, thereby increasing the light collecting power of the on-chip lenses 33. In addition, the refractive index of the interlayer insulating film 35 is lower than the refractive index of a bonding resin 36 thereon. Assuming that the refractive index of the bonding resin 36 is n₁, the refractive index of the interlayer insulating film 35 is n₂, and the refractive index of the on-chip lenses 33 is n₃, (the refractive index n₂ of the interlayer insulating film 35)<(the refractive index n₁ of the bonding resin 36)<<(the refractive index n₃ of the on-chip lenses 33) holds. The refractive index n₁ of the bonding resin 36 is the same as that of the light-transmissive substrate 37.

A light-transmissive substrate 37 is bonded to the upper side of the interlayer insulating film 35 with the bonding resin 36. The light-transmissive substrate 37 is, for example, a substrate having a light-transmissive property such as a glass substrate or the like. The light-transmissive substrate 37 also has a function of protecting the on-chip lenses 33.

The first surface (upper surface) on the light incident surface side of the light-transmissive substrate 37 is formed flat. Meanwhile, as illustrated in FIG. 1, the second surface (lower surface) opposite to the first surface of the light-transmissive substrate 37 has different thicknesses in a central region 41 facing the pixel region 43 and an outer peripheral region 42 that is an outer chip outer peripheral portion. Specifically, the thickness T1 of the central region 41 is, for example, about 20 to 30 μm, and the thickness T2 of the outer peripheral region 42 is, for example, about 50 to 60 μm, and the central region 41 is formed to be thinner than the outer peripheral region 42.

The central region 41, which is a thin portion of the light-transmissive substrate 37, is a region expanded outward by a predetermined width L (>0) from the pixel region 43 of the upper substrate 12 in which the photodiodes 71 are formed in units of pixels. The width M (>0) of the outer peripheral region 42 needs to be a certain width or more in order to prevent damage such as breakage, cracks, or the like due to external impact, and is, for example, 30 μm or more.

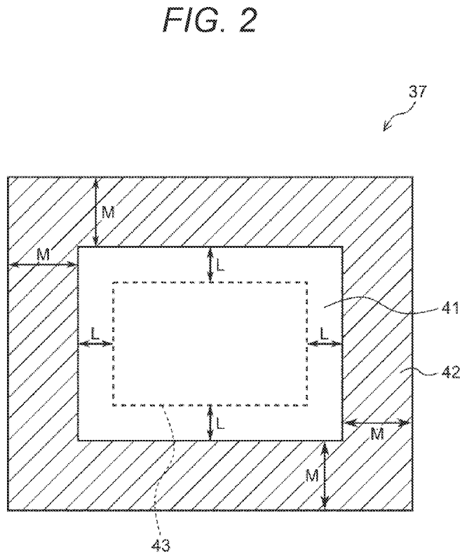

The arrangement relationship between the pixel region 43, the central region 41 formed with a small thickness T1, and the outer peripheral region 42 formed with a thickness T2 thicker than that of the central region is as illustrated in FIG. 2 in plan view.

FIG. 2 is a plan view of the light-transmissive substrate 37, and in FIG. 2, the outer peripheral region 42 is hatched in order to facilitate distinction between the central region 41 and the outer peripheral region 42.

The central region 41 of the light-transmissive substrate 37 is a region obtained by further expanding the periphery of the pixel region 43 by a distance L in plan view, and the outer peripheral region 42 has a rectangular shape formed by a region at a distance M in the up-down and left-right directions from the periphery of the central region 41.

The solid-state imaging device 1 having the above-described structure is a back-illuminated solid-state imaging device in which the on-chip lenses 33 are formed on the back surface side of the silicon substrate 31 in which photodiodes 71 are formed in units of pixels, and light is incident from the back surface side.

Further, the solid-state imaging device 1 is a solid-state imaging device having a cavityless structure in which the light-transmissive substrate 37 that protects the on-chip lenses 33 is bonded to the interlayer insulating film 35 of the upper substrate 12 without a gap by the bonding resin 36.

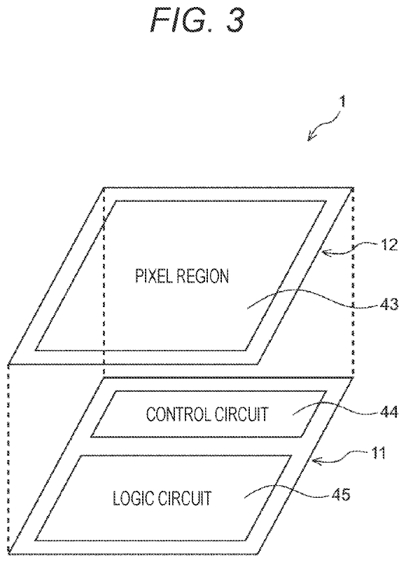

FIG. 3 is a perspective view illustrating a configuration example of each of the lower substrate 11 and the upper substrate 12.

In the upper substrate 12, only photodiodes 71 as photoelectric conversion sections and the pixel region 43 in which transfer transistors or the like that transfers a charge generated by the photodiodes 71 are formed in units of pixels are disposed, and in the lower substrate 11, a control circuit 44 that controls each pixel and a logic circuit 45 such as a signal processing circuit that processes a pixel signal output from each pixel are disposed.

As described above, by forming and stacking both the control circuit 44 and the logic circuit 45 on the lower substrate 11 different from the upper substrate 12 of the pixel region 43, the size of the solid-state imaging device 1 can be reduced as compared with a case where the pixel region 43, the control circuit 44, and the logic circuit 45 are disposed in one semiconductor substrate in the planar direction.

<2. Circuit Configuration Example of Solid-State Imaging Device>

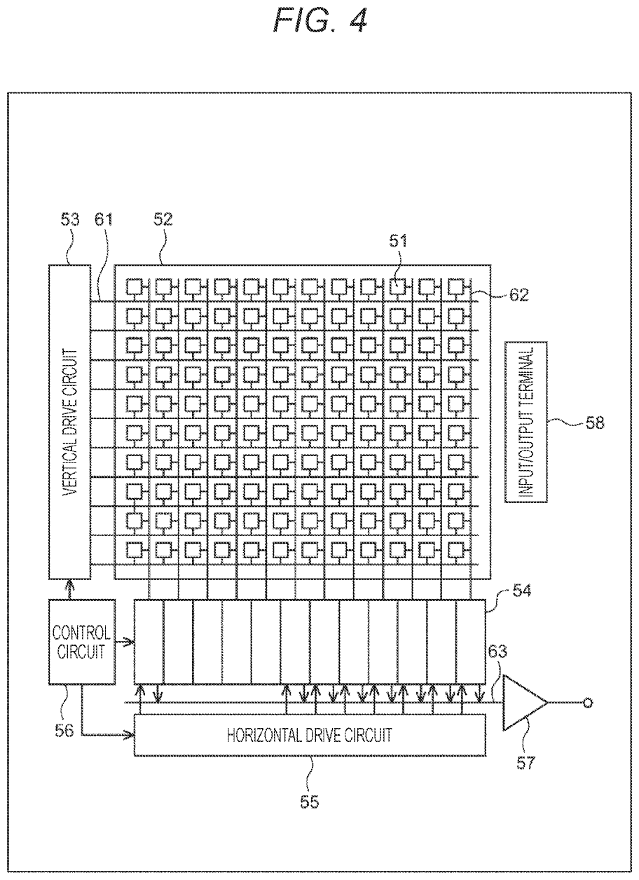

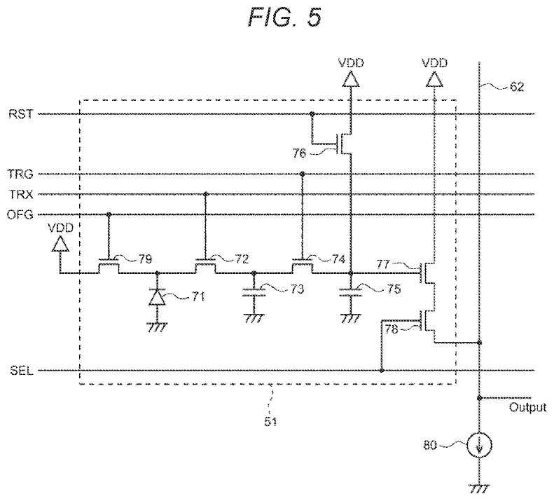

A circuit configuration of the solid-state imaging device 1 will be described with reference to FIGS. 4 and 5.

FIG. 4 illustrates a circuit configuration example of the solid-state imaging device 1.

The solid-state imaging device 1 includes a pixel array section 52 in which pixels 51 are arranged in a two-dimensional lattice, a vertical drive circuit 53, a column signal processing circuit 54, a horizontal drive circuit 55, a control circuit 56, an output circuit 57, an input/output terminal 58, and the like.

The pixel 51 includes a photodiode 71 and a plurality of pixel transistors, and a detailed configuration example of the pixel 51 will be described later with reference to FIG. 5.

The vertical drive circuit 53 includes, for example, a shift register, selects a predetermined pixel drive line 61, supplies a pulse for driving the pixels 51 to the selected pixel drive line 61, and drives the pixels 51 in units of rows. That is, the vertical drive circuit 53 sequentially selects and scans each pixel 51 of the pixel array section 52 in the vertical direction in units of rows, and supplies a pixel signal based on a signal charge generated according to the received light amount in the photoelectric conversion section of each pixel 51 to the column signal processing circuit 54 through a vertical signal line 62.

The column signal processing circuit 54 is disposed for each column of the pixels 51, and performs signal processing such as noise removal or the like on the signals output from the pixels 51 of one row for each pixel column. For example, the column signal processing circuit 54 performs signal processing such as correlated double sampling (CDS) for removing pixel-specific fixed pattern noise, AD conversion, and the like.

The horizontal drive circuit 55 includes, for example, a shift register, sequentially selects each of the column signal processing circuits 54 by sequentially outputting horizontal scanning pulses, and causes each of the column signal processing circuits 54 to output a pixel signal to a horizontal signal line 63.

The control circuit 56 receives an input clock and data instructing an operation mode and the like, and controls the operation and timing of the entire device. More specifically, the control circuit 56 generates a clock signal or a control signal serving as a reference of operations of the vertical drive circuit 53, the column signal processing circuit 54, the horizontal drive circuit 55, and the like on the basis of the vertical synchronization signal, the horizontal synchronization signal, and the master clock. Then, the control circuit 56 outputs the generated clock signal and control signal to the vertical drive circuit 53, the column signal processing circuit 54, the horizontal drive circuit 55, and the like.

The output circuit 57 performs signal processing on the signals sequentially supplied from each of the column signal processing circuits 54 through the horizontal signal line 63, and outputs the processed signals. For example, the output circuit 57 may perform only buffering or may perform various digital signal processing or the like such as black level adjustment, column variation correction, and the like. The input/output terminal 58 exchanges signals with the outside.

The solid-state imaging device 1 configured as described above is a CMOS image sensor called a column AD system in which the column signal processing circuit 54 that performs CDS processing and AD conversion processing is disposed for each pixel column.

<Example of Pixel Circuit>

FIG. 5 illustrates a circuit configuration example of the pixel 51.

The pixel 51 illustrated in FIG. 5 illustrates a configuration that implements an electronic global shutter function.

The pixel 51 includes a photodiode 71, a first transfer transistor 72, a memory section (MEM) 73, a second transfer transistor 74, a floating diffusion region (FD) 75, a reset transistor 76, an amplification transistor 77, a selection transistor 78, and a discharge transistor 79.

The photodiode 71 is a photoelectric conversion section that generates and accumulates a charge (signal charge) corresponding to the received light amount. The anode terminal of the photodiode 71 is grounded, and the cathode terminal is connected to the memory section 73 via the first transfer transistor 72. In addition, the cathode terminal of the photodiode 71 is also connected to the discharge transistor 79 for discharging unnecessary charges.

When turned on by the transfer signal TRX, the first transfer transistor 72 reads the charge generated by the photodiode 71 and transfers the charge to the memory section 73. The memory section 73 is a charge holding section that temporarily holds a charge until the charge is transferred to the FD 75.

When turned on by the transfer signal TRG, the second transfer transistor 74 reads the charge held in the memory section 73 and transfers the charge to the FD 75.

The FD 75 is a charge holding section that holds the charge read from the memory section 73 in order to read the charge as a signal. When turned on by a reset signal RST, the reset transistor 76 resets the potential of the FD 75 by discharging the charge accumulated in the FD 75 to the constant voltage source VDD.

The amplification transistor 77 outputs a pixel signal corresponding to the potential of the FD 75. That is, the amplification transistor 77 constitutes a source follower circuit with a load MOS 80 as a constant current source, and a pixel signal indicating a level according to the charge accumulated in the FD 75 is output from the amplification transistor 77 to the column signal processing circuit 54 (FIG. 4) via the selection transistor 78. The load MOS 80 is disposed, for example, in the column signal processing circuit 54.

The selection transistor 78 is turned on when the pixel 51 is selected by the selection signal SEL, and outputs the pixel signal of the pixel 51 to the column signal processing circuit 54 via the vertical signal line 62.

When turned on by the discharge signal OFG, the discharge transistor 79 discharges the unnecessary charge accumulated in the photodiode 71 to the constant voltage source VDD.

The transfer signals TRX and TRG, the reset signal RST, the discharge signal OFG, and the selection signal SEL are supplied from the vertical drive circuit 53 via the pixel drive line 61.

The operation of the pixel 51 will be briefly described.

First, before exposure is started, the discharge transistor 79 is turned on by supplying the discharge signal OFG at the high level to the discharge transistor 79, the charge accumulated in the photodiode 71 is discharged to the constant voltage source VDD, and the photodiodes 71 of all the pixels are reset.

After the photodiode 71 is reset, when the discharge transistor 79 is turned off by the low-level discharge signal OFG, exposure is started in all the pixels of the pixel array section 52.

When a predetermined exposure time has elapsed, the first transfer transistor 72 is turned on by the transfer signal TRX in all the pixels of the pixel array section 52, and the charge accumulated in the photodiode 71 is transferred to the memory section 73.

After the first transfer transistor 72 is turned off, the charges held in the memory section 73 of each pixel 51 are sequentially read out to the column signal processing circuit 54 in units of rows. In the read operation, the second transfer transistor 74 of the pixel 51 of the read row is turned on by the transfer signal TRG, and the charge held in the memory section 73 is transferred to the FD 75. Then, when the selection transistor 78 is turned on by the selection signal SEL, a signal indicating a level corresponding to the charge accumulated in the FD 75 is output from the amplification transistor 77 to the column signal processing circuit 54 via the selection transistor 78.

As described above, in the pixel 51 having the pixel circuit in FIG. 5, the exposure time is set to be the same in all the pixels of the pixel array section 52, and after the exposure is finished, the charge is temporarily held in the memory section 73, and the global shutter system operation (imaging) of sequentially reading the charge from the memory section 73 in units of rows is possible.

Note that the circuit configuration of the pixel 51 is not limited to the configuration illustrated in FIG. 5, and for example, a circuit configuration that does not include the memory section 73 and performs an operation by a so-called rolling shutter system can be adopted.

Further, the pixel 51 may have a shared pixel structure in which some pixel transistors are shared by a plurality of pixels. For example, a configuration or the like in which the first transfer transistor 72, the memory section 73, and the second transfer transistor 74 are included in units of pixels 51, and the FD 75, the reset transistor 76, the amplification transistor 77, and the selection transistor 78 are shared by a plurality of pixels such as four pixels or the like can be adopted.

<3. Effects of Device Structure in FIG. 1>

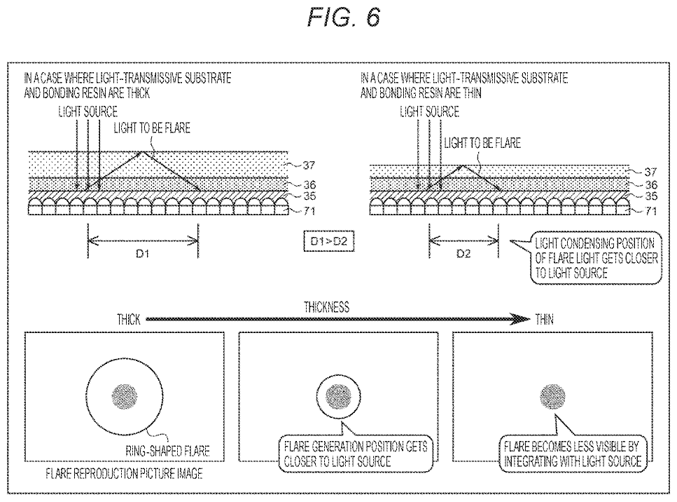

A problem of the cavityless structure to be solved by the solid-state imaging device 1 in FIG. 1 will be described with reference to FIG. 6.

In the cavityless structure in which the light-transmissive substrate 37 and the on-chip lenses 33 of the upper substrate 12 are bonded without a gap by the bonding resin 36, as illustrated in the upper part of FIG. 6, high-order light of diffracted light reflected by the front surface or the like of the upper substrate 12 and incident on the light-transmissive substrate 37 may return to the pixel region 43 without being totally reflected by the back surface (lower surface) after being totally reflected by the front surface (upper surface) of the light-transmissive substrate 37.

That is, in the cavityless structure, since the space between the upper substrate 12 and the light-transmissive substrate 37 is filled with the bonding resin 36 having the same refractive index as that of the light-transmissive substrate 37 without any gap, the reflected light totally reflected on the upper surface of the light-transmissive substrate 37 is not reflected at the interface between the light-transmissive substrate 37 and the bonding resin 36 but returns to the pixel region 43 of the upper substrate 12 as it is, and high-order light of the diffracted light may become a ring-shaped flare and adversely affect image quality.

In order to solve flare due to high-order diffracted light, it is desirable to form the light-transmissive substrate 37 and the bonding resin 36 to be thin. In a case where the thicknesses of the light-transmissive substrate 37 and the bonding resin 36 are formed to be thin, as illustrated in the lower part of FIG. 6, the generation position of the ring flare can be brought close to the light source position of the incident light, and the visibility of the flare can be lowered by integrating with the light source.

However, in a case where the thicknesses of the light-transmissive substrate 37 and the bonding resin 36 are formed to be thin, the following problems occur.

In a case where the thickness of the light-transmissive substrate 37 is reduced, the strength decreases, and in particular, the light-transmissive substrate 37 constituted by a material such as glass or the like may be broken due to an external impact or the like at the end portion of the chip.

Meanwhile, in a case where the light-transmissive substrate 37 is a glass substrate, the bonding resin 36 has a function of suppressing the alpha rays generated from the glass substrate, but in a case where the thickness of the bonding resin 36 is reduced, the function of suppressing the alpha rays is not sufficiently fulfilled, and electrons caused by the alpha rays from the light-transmissive substrate 37 are generated in the photoelectric conversion section, and may become a defect called a white defect.

Therefore, as illustrated in FIG. 1, the solid-state imaging device 1 secures the thickness of the bonding resin 36 and has a structure in which the function of suppressing the alpha ray generated from the light-transmissive substrate 37 is sufficiently exerted by forming the upper surface of the light-transmissive substrate 37 to be the device surface to be flat and forming the thickness T1 of the light-transmissive substrate 37 in the central region 41 facing the pixel region 43 to be thin.

In addition, by forming the thickness T2 of the outer peripheral region 42 including the end portion of the light-transmissive substrate 37 to be thicker than the thickness T1 of the central region 41, strength is secured, and damage due to external impact or the like is prevented. Meanwhile, the outer peripheral region 42 is formed to be thinner than the pixel region 43 in terms of the film thickness of the bonding resin 36.

That is, in the central region 41 overlapping the pixel region 43 in plan view, the thickness of the bonding resin 36 is secured and the light-transmissive substrate 37 is formed to be thin in order to suppress the alpha rays. On the other hand, in the outer peripheral region 42 that does not overlap the pixel region 43, the function of suppressing the alpha rays is not necessary, and thus, instead of reducing the film thickness of the bonding resin 36, the thickness of the light-transmissive substrate 37 is formed to be thick to secure the strength.

As described above, by increasing the thickness of one of the bonding resin 36 and the light-transmissive substrate 37 in the central region 41 and the outer peripheral region 42 as necessary and reducing the thickness of the other, the overall thickness can be formed to be thinner, and flare due to high-order diffracted light is solved.

Therefore, according to the structure described above of the solid-state imaging device 1, it is possible to solve flare due to high-order diffracted light, to prevent occurrence of white defects, and to secure the strength of the light-transmissive substrate 37.

<4. Derivation of Distance L>

As illustrated in FIGS. 1 and 2, the central region 41 having a small thickness of the light-transmissive substrate 37 is a region expanded outward from the pixel region 43 by a predetermined width L, and how large the width L needs to be secured will be described.

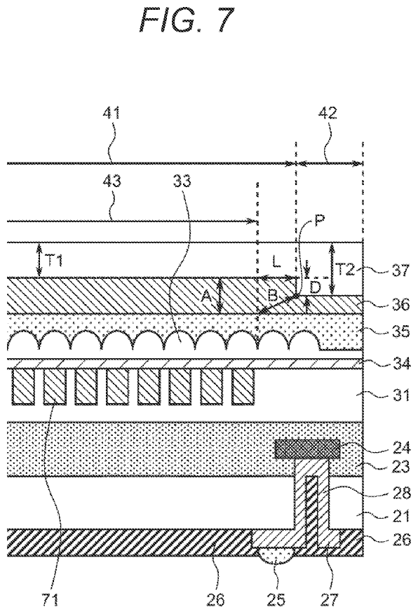

FIG. 7 is a cross-sectional view of the vicinity of an end portion of the solid-state imaging device 1 in FIG. 1.

When the film thickness of the bonding resin 36 in the central region 41 overlapping the pixel region 43 in plan view is A, the film thickness A needs to be a certain value or more in order to block the alpha ray, and is, for example, 50 μm.

A difference in thickness between the thickness T1 of the central region 41 of the light-transmissive substrate 37 and the thickness T2 of the outer peripheral region 42 is defined as D (hereinafter, referred to as a step D), and a corner portion on the inner side of the bottom surface of the outer peripheral region 42 of the light-transmissive substrate 37 closest to the pixel region 43 is defined as P.

The film thickness A in the direction perpendicular to the plane of the pixel region 43 needs to be a certain value or more in order to block the alpha ray, and the distance B between the corner portion P on the inner side of the bottom surface of the outer peripheral region 42 of the light-transmissive substrate 37 closest to the pixel region 43 and the end portion of the pixel region 43 similarly needs to be separated by the same distance as the film thickness A.

Therefore, the set distance L is a distance at which the distance B is separated by at least the distance A.

The distance A, the distance (A-D), and the distance B are in relationship of:

B²=(A−D)²+L²

Therefore, when deformation is performed with L as the left side, it can be expressed as:

[Mathematical formula 1]

L=\sqrt{B²−(A−D)²} (1)

The minimum value of the distance B is the distance A, and thus by substituting A for B, it can be expressed as:

[Mathematical formula 2]

L=\sqrt{A²−(A−D)²}=\sqrt{2AD−D²} (2)

Therefore, for example, when the distance A is 50 μm and the step D is 10 μm, the distance L is 30 μm, and thus the distance L needs to be set to at least 30 μm or more.

<In a Case where there is OPB Region>

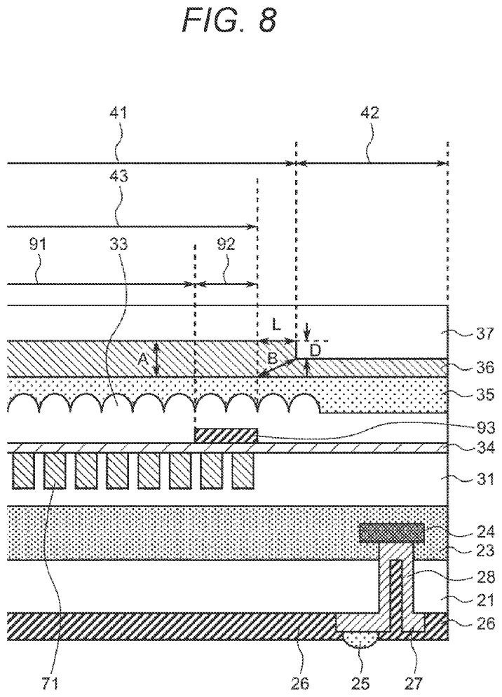

Note that, as illustrated in FIG. 8, the pixel region 43 may include an effective pixel region 91 and an OPB region 92. The effective pixel region 91 is a region in which the pixels 51 that generate charges according to the amount of incident light are arranged, and the pixel region 43 in FIG. 1 is an example in which the entire region is the effective pixel region 91.

The OPB region 92 is a region in which a light shielding film 93 is formed on the upper portion of the photodiode 71 of each pixel 51, and is a region in which the pixels 51 that detect the black-level reference potential without incident light are arranged. As a material of the light shielding film 93, for example, tungsten, aluminum, copper, or the like is used.

As described above, in a case where the pixel region 43 includes the effective pixel region 91 and the OPB region 92, the central region 41 is a region expanded outward from the end portion of the OPB region 92 by the distance L in the expression (2).

<5. Method of Manufacturing Solid-State Imaging Device>

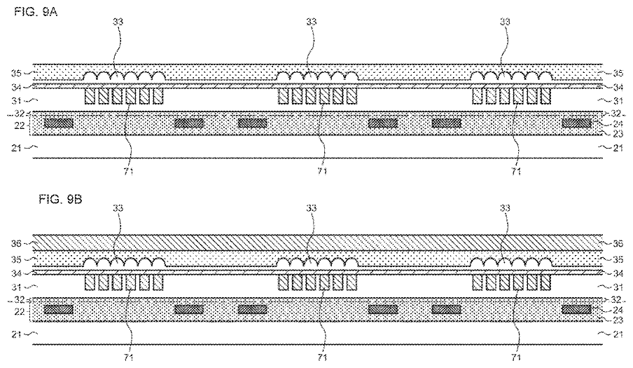

Next, a method of manufacturing the solid-state imaging device 1 in FIG. 1 will be described with reference to FIGS. 9 to 13.

The solid-state imaging device 1 is manufactured by a wafer level process of forming a required circuit or the like in a region (hereinafter, referred to as a chip region) to be each chip portion of a semiconductor substrate in a wafer state. FIGS. 9 to 14 further illustrate, in a simplified manner, FIG. 1 for portions corresponding to three chip regions arranged in the planar direction in the semiconductor substrate in the wafer state for convenience of space limitations.

First, as illustrated in A of FIG. 9, the silicon substrate 31 in a wafer state in which the circuit of each pixel 51 including the photodiode 71 is formed and the silicon substrate 21 in a wafer state in which the control circuit 44 and the logic circuit 45 are formed are bonded together.

More specifically, the photodiode 71 of each pixel 51 is formed in each chip region of the silicon substrate 31 in a wafer state, and the wiring layer 32 is formed on one surface (front surface) of the silicon substrate 31. In addition, the multilayer wiring layer 22 to be the control circuit 44 and the logic circuit 45 is formed on one surface (front surface) of the silicon substrate 21 in a wafer state. The control circuit 44 and the logic circuit 45 are also formed corresponding to each chip region. The internal electrodes 24 are included in parts of the logic circuit 45. Thereafter, the wiring layer 32 of the silicon substrate 31 in the wafer state and the multilayer wiring layer 22 of the silicon substrate 21 in the wafer state are bonded together by plasma bonding or bonding with an adhesive. An alternate long and short dash line indicates a bonding surface between the wiring layer 32 of the silicon substrate 31 and the multilayer wiring layer 22 of the silicon substrate 21. The on-chip lenses 33 formed on the light incident surface side of the silicon substrate 31 in the wafer state and the interlayer insulating film 35 thereon may be formed before bonding or may be formed after bonding.

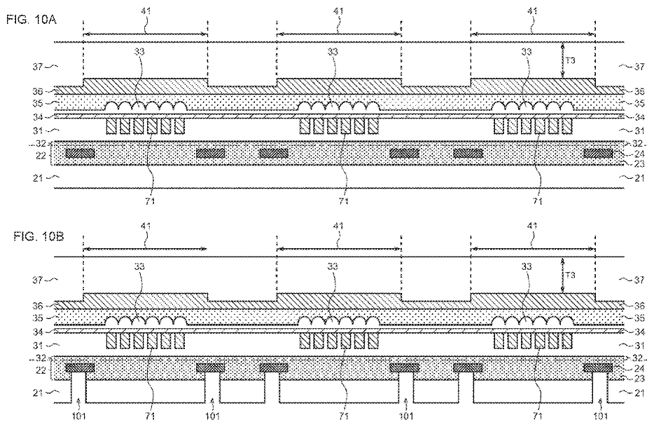

Next, as illustrated in B of FIG. 9, the bonding resin 36 is formed on the upper surface of the interlayer insulating film 35. Then, as illustrated in A of FIG. 10, the light-transmissive substrate 37 in a wafer state is bonded by the bonding resin 36.

In the light-transmissive substrate 37 in a wafer state to be bonded, as illustrated in A of FIG. 10, a recessed portion is formed in a portion corresponding to the central region 41 of each chip region on the lower surface on the on-chip lenses 33 side. That is, the light-transmissive substrate 37 in a state in which the step D is formed between the central region 41 and the outer peripheral region 42 of each chip region is bonded to the light incident surface side of the silicon substrate 31 in the wafer state. When the light-transmissive substrate 37 in which the recessed portion is formed is bonded, the bonding resin 36 formed flat as in B of FIG. 9 is filled up to the recessed portion.

Note that the thickness T3 of the central region 41 of the light-transmissive substrate 37 at the time of bonding is in a state of being thicker than the thickness T1 of the central region 41 of the solid-state imaging device 1 in the completed state. As a result, strength required for handling in subsequent steps is secured.

Next, as illustrated in B of FIG. 10, the through-holes 101 are formed at positions corresponding to the internal electrodes 24 of the multilayer wiring layer 22 from the back surface side of the silicon substrate 21 in the wafer state.

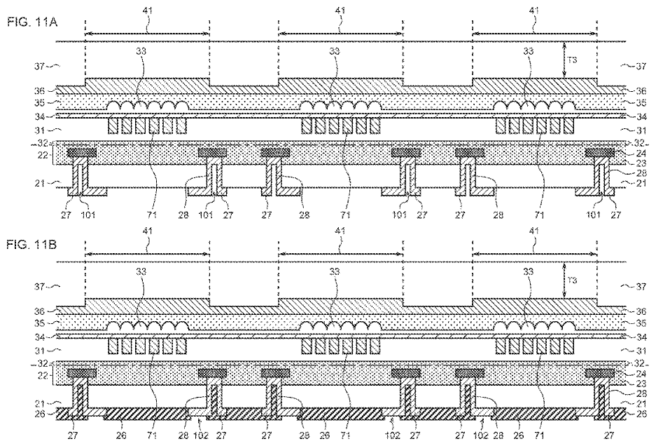

Next, as illustrated in A of FIG. 11, the connection conductors 28 on the upper surface of the internal electrodes 24 and the inner peripheral surface of the through-holes and the rewiring lines 27 on the back surface of the silicon substrate 21 are simultaneously formed using a resist material provided with an opening pattern in a desired region as a mask by an electrolytic plating method or the like. Note that, although not illustrated, an insulating film is formed between the rewiring lines 27 and the connection conductors 28, and the silicon substrate 21. For example, copper (Cu) is used as the material of the rewiring lines 27 and the connection conductors 28, and the film thickness of the rewiring lines 27 is set to, for example, several μm to several tens μm.

Next, as illustrated in B of FIG. 11, parts on the rewiring lines 27 are set as openings 102, and the upper surfaces of the other rewiring lines 27, the connection conductors 28, and the silicon substrate 21 are covered with the protective film 26. As a material of the protective film 26, for example, a solder resist which is an organic material is used. Openings 102 correspond to portions where the solder bumps 25 are formed.

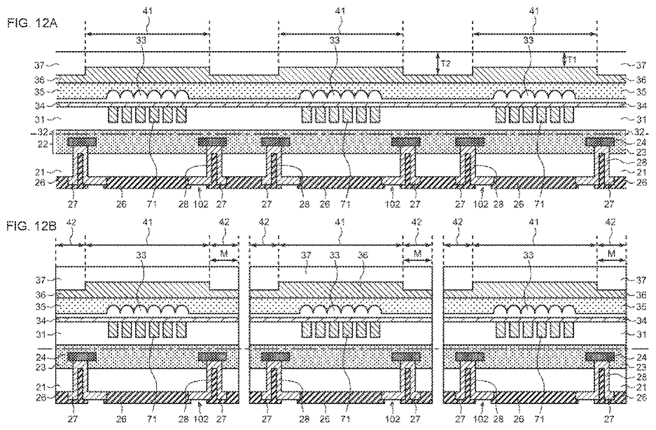

Next, as illustrated in A of FIG. 12, the light-transmissive substrate 37 in a wafer state is thinned to a desired film thickness by a chemical mechanical polishing method (CMP) or the like. As a result, the thickness of the light-transmissive substrate 37 in the central region 41 becomes T1, and the thickness of the outer peripheral region 42 becomes T2.

Next, as illustrated in B of FIG. 12, the bonded substrate including the silicon substrates 21 and 31 in the wafer state and the light-transmissive substrate 37 is divided in units of chips. The width M of the outer peripheral region 42 after dividing in units of chips is, for example, 30 μm or more, and a width necessary for preventing damage due to external impact is secured.

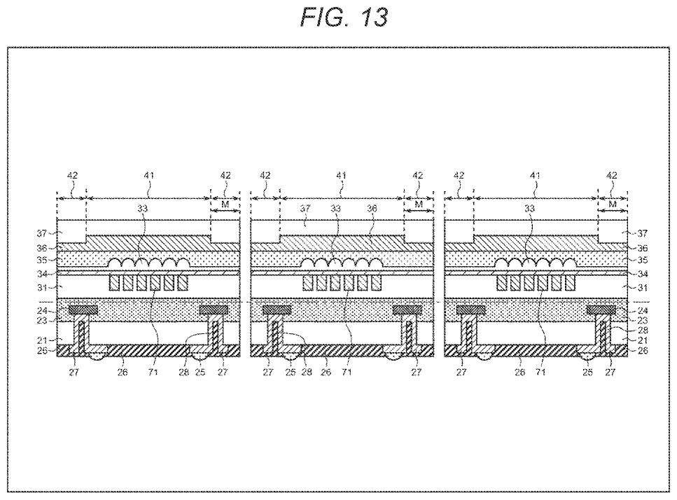

Finally, as illustrated in FIG. 13, the solder bumps 25 are formed on the rewiring lines 27 of the openings 102 of the silicon substrate 31 of the bonded substrate divided in units of chips to complete the solid-state imaging device 1 in FIG. 1.

The solder bumps 25 are bonding portions that serve as contact points between the solid-state imaging device 1 and a module substrate on which the solid-state imaging device 1 is mounted. Alternatively, back electrodes equivalent to the solder bumps 25 may be formed by forming a metal material such as copper, nickel, or the like in the openings 102 by a plating method, in addition to forming the solder bumps into bump shapes by disposing ball-like solder materials and applying heat treatment.

As described above, the solid-state imaging device 1 in FIG. 1 is manufactured by a wafer level process in which circuits of the respective pixels 51 including the photodiodes 71, the control circuit 44 and the logic circuit 45 that control the respective pixels, and the like are simultaneously formed in the respective chip regions arranged in a lattice shape on a semiconductor substrate in a wafer state and then divided into chip sizes.

In the wafer state, the light-transmissive substrate 37 is processed in advance so that the central region 41 and the outer peripheral region 42 of each chip region have different thicknesses, and then bonded to the silicon substrates 21 and 31 in the wafer state. Then, the silicon substrates 21 and 31 in the wafer state and the light-transmissive substrate 37 are divided in units of chips.

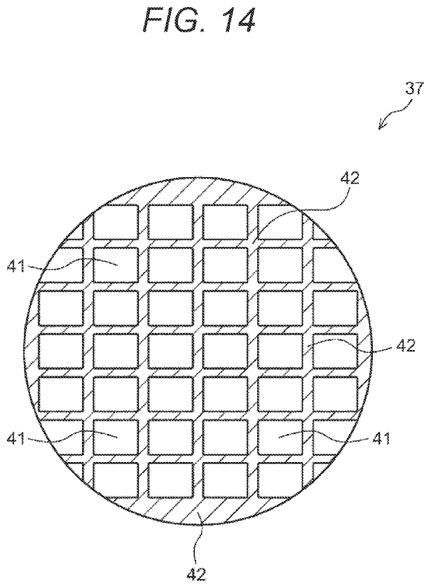

FIG. 14 is a plan view of the light-transmissive substrate 37 in a wafer state formed such that the central region 41 and the outer peripheral region 42 have different thicknesses.

In the wafer state, the central region 41 of each chip region is formed to be thinner by the step D, and the outer peripheral region 42 is formed in a lattice shape. When the light-transmissive substrate 37 of FIG. 14 is divided in units of chips, the plan view illustrated in FIG. 2 is obtained.

<6. Other Shape Examples of Light-Transmissive Substrate>

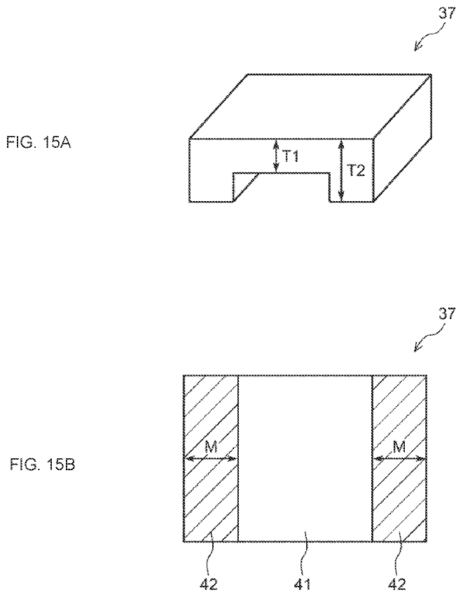

Another shape example of the light-transmissive substrate 37 applicable to the solid-state imaging device 1 in FIG. 1 will be described with reference to FIGS. 15 to 18.

FIG. 15 is a view illustrating another first shape example of the light-transmissive substrate 37. A of FIG. 15 is a perspective view of the light-transmissive substrate 37 of a chip size, and B of FIG. 15 is a plan view of the light-transmissive substrate 37 of a bonding surface with the bonding resin 36.

As illustrated in B of FIG. 15, the light-transmissive substrate 37 includes an outer peripheral region 42 having a thickness T2, which is an outer peripheral portion having a width M from an end portion corresponding to two sides in the left-right direction of the rectangular chip, and a central region 41 formed inside the outer peripheral region and having a thickness T1 smaller than the thickness T2. As described above, the light-transmissive substrate 37 may have a shape in which the thick outer peripheral region 42 is formed only on two sides of the rectangular chip.

When only two sides in the left-right direction of the rectangular chip are the thick outer peripheral region 42, it seems that the strength of the two sides in the up-down direction is weak, but in view of the stress applied to the chip, the portions where the strength is required are the corner portions of the four corners of the chip. As can be seen from B of FIG. 15, since the four corners of the chip are the outer peripheral region 42 formed to be thick, the strength is secured.

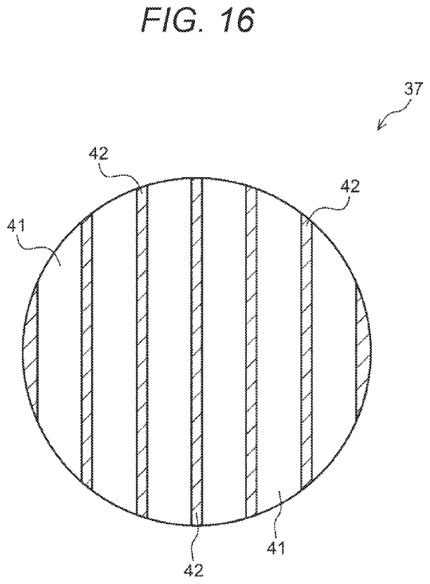

FIG. 16 is a plan view of the light-transmissive substrate 37 in a wafer state before the light-transmissive substrate 37 in FIG. 15 is divided in units of chips.

As illustrated in FIG. 16, the light-transmissive substrate 37 of the first shape example has a shape in which thick outer peripheral regions 42 are disposed in a stripe shape in a wafer state. By forming the outer peripheral region 42 in a stripe shape in this manner, in a case where the silicon substrates 21 and 31 and the light-transmissive substrate 37 are bonded in a wafer state with the bonding resin 36, it is possible to alleviate positional deviation accuracy in a direction parallel to the stripe which is the up-down direction in FIG. 16.

Note that FIGS. 15 and 16 illustrate an example in which two sides in the left-right direction of the rectangular chip are the outer peripheral region 42, but may have a shape in which two sides in the up-down direction are the outer peripheral region 42. That is, the first shape example can be a line shape in which a constant width M along two sides of the rectangular chip in either the left-right direction or the up-down direction is set as the outer peripheral region 42.

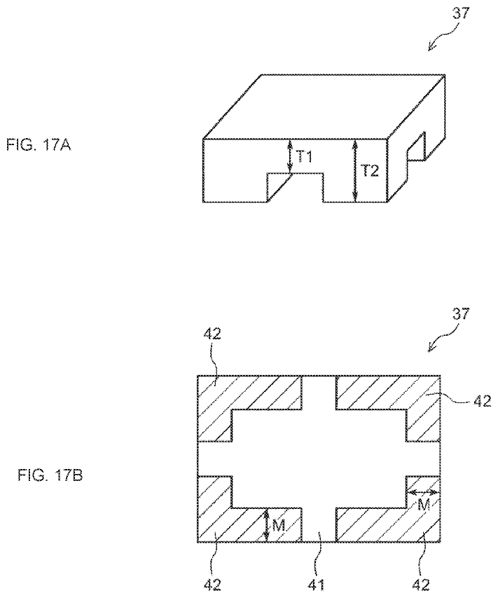

FIG. 17 is a view illustrating another second shape example of the light-transmissive substrate 37. A of FIG. 17 is a perspective view of the light-transmissive substrate 37 of a chip size, and B of FIG. 17 is a plan view of the light-transmissive substrate 37 of a bonding surface with the bonding resin 36.

As illustrated in B of FIG. 17, the outer peripheral region 42 having the thickness T2 of the light-transmissive substrate 37 has a shape in which an L shape is disposed from each corner portion of the rectangle along two sides forming the corner portions except for the central portion of each side of the rectangle. In other words, the light-transmissive substrate 37 of FIG. 17 has a shape in which central portions of four sides of the outer peripheral region 42 of the light-transmissive substrate 37 of FIG. 2 on the upper, lower, left, and right sides are changed to the central region 41. Also in such a second shape example, since the four corners of the chip are the outer peripheral region 42 formed to be thick, the strength is secured.

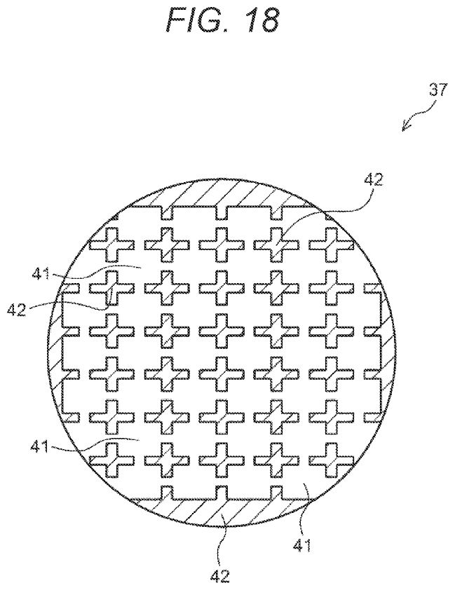

FIG. 18 is a plan view of the light-transmissive substrate 37 in a wafer state before the light-transmissive substrate 37 in FIG. 17 is divided in units of chips.

The light-transmissive substrate 37 of the second shape example has a shape in which the thick outer peripheral regions 42 are regularly disposed in cross shapes in the wafer state as illustrated in FIG. 18. By forming the outer peripheral region 42 in a cross shape in this manner, a flow path through which the bonding resin 36 can flow is formed in the up-down and left-right directions of each chip region. That is, in a case where the silicon substrates 21 and 31 and the light-transmissive substrate 37 are bonded in a wafer state with the bonding resin 36, the extra bonding resin 36 is discharged through any flow path in the up-down and left-right directions in FIG. 18, so that the extra bonding resin 36 does not stay in a specific chip region to make the film thickness larger, and the bonding resin 36 does not run short in a specific chip region to make the film thickness smaller. That is, the uniformity of the film thickness of the bonding resin 36 is enhanced, and good bonding can be performed.

Note that, in the second shape example in FIGS. 17 and 18, recesses serving as flow paths of the bonding resin 36 are formed in all of the up-down and left-right directions of each rectangular chip region, but may be formed in at least one direction.

Further, in the wafer state of FIG. 18, recesses are formed in all of the up-down and left-right directions of each chip region of the lattice shape, but the recesses may be formed only in an arbitrary direction. For example, recesses in the right direction may be formed in odd-numbered rows of each lattice-shaped chip region, and recesses in the left direction may be formed in even-numbered rows. In addition, recesses in any of the up-down and left-right directions may be formed in units of every other chip region or every two chip regions.

Also in the first and second shape examples illustrated in FIGS. 15 to 18, in the central region 41 overlapping the pixel region 43 in plan view, in order to suppress the alpha ray, the thickness of the bonding resin 36 is secured, and the light-transmissive substrate 37 is formed to be thin. On the other hand, in the outer peripheral region 42 that does not overlap the pixel region 43, instead of reducing the film thickness of the bonding resin 36, the light-transmissive substrate 37 is formed to be thick, and the strength is secured.

In addition, by increasing the thickness of one of the bonding resin 36 and the light-transmissive substrate 37 in the central region 41 and the outer peripheral region 42 as necessary and reducing the thickness of the other, the overall thickness can be formed to be thinner, and the flare due to high-order diffracted light is solved.

Therefore, also in the first and second shape examples, the flare due to the high-order diffracted light is solved, the occurrence of white defects is prevented, and the strength of the light-transmissive substrate 37 is secured.

<7. Second Embodiment of Solid-State Imaging Device>

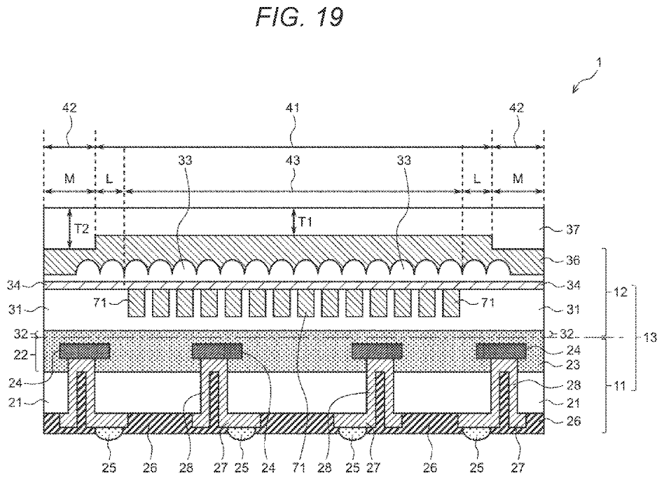

FIG. 19 is a cross-sectional view illustrating a configuration example of a second embodiment of a solid-state imaging device to which the present technology is applied.

In FIG. 19, portions corresponding to those of the first embodiment illustrated in FIG. 1 are denoted by the same reference numerals, and description of the portions will be omitted as appropriate.

In the second embodiment of FIG. 19, the interlayer insulating film 35 formed on the on-chip lenses 33 in the first embodiment illustrated in FIG. 1 is omitted. That is, in the solid-state imaging device 1 in FIG. 19, the bonding resin 36 is formed on the on-chip lenses 33, and the light-transmissive substrate 37 is bonded thereto.

As described above, the interlayer insulating film 35 can be omitted. However, as described with reference to FIG. 1, by providing the interlayer insulating film 35 on the on-chip lenses 33 using a material having a refractive index lower than that of the on-chip lenses 33, it is possible to provide a refractive index difference between the on-chip lenses 33 and the interlayer insulating film 35 thereon, and it is possible to increase the light collecting power of the on-chip lenses 33.

<8. Third Embodiment of Solid-State Imaging Device>

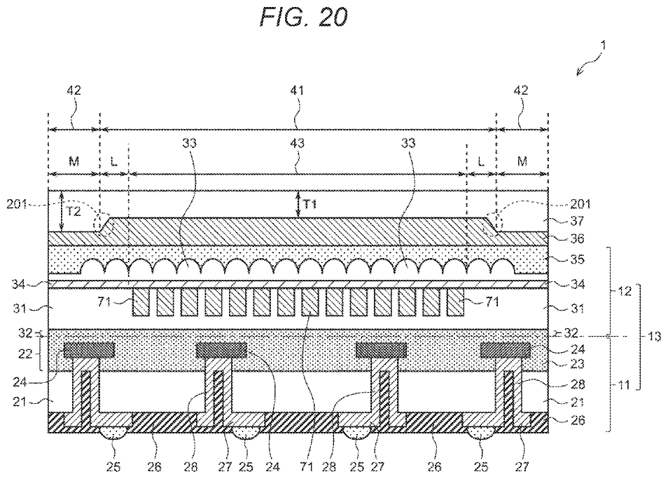

FIG. 20 is a cross-sectional view illustrating a configuration example of a third embodiment of a solid-state imaging device to which the present technology is applied.

In FIG. 20, portions corresponding to those of the first embodiment illustrated in FIG. 1 are denoted by the same reference numerals, and description of the portions will be omitted as appropriate.

The third embodiment in FIG. 20 is different from the first embodiment illustrated in FIG. 1 in that a step portion 201 between the central region 41 and the outer peripheral region 42 of the light-transmissive substrate 37, in other words, an inner peripheral side surface on the central region 41 side of the outer peripheral region 42 of the light-transmissive substrate 37 is formed in a tapered shape inclined inward, and is common to the first embodiment in other points.

As described above, by forming the inner peripheral side surface of the outer peripheral region 42 in the tapered shape, it is possible to alleviate the stress applied to the step portion 201 and to prevent breakage or cracks of the light-transmissive substrate 37. Further, it is possible to improve embeddability of the bonding resin 36 in the step portion 201 at the time of bonding the light-transmissive substrate 37.

<9. Fourth Embodiment of Solid-State Imaging Device>

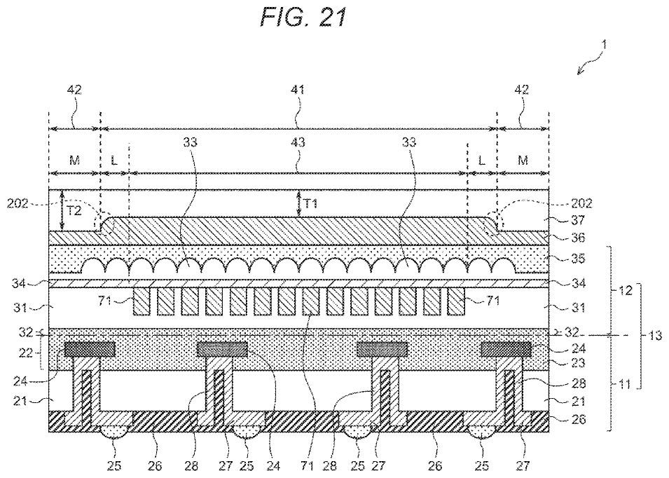

FIG. 21 is a cross-sectional view illustrating a configuration example of a fourth embodiment of a solid-state imaging device to which the present technology is applied.

In FIG. 21, portions corresponding to those of the first embodiment illustrated in FIG. 1 are denoted by the same reference numerals, and description of the portions will be omitted as appropriate.

The fourth embodiment in FIG. 21 is different from the first embodiment illustrated in FIG. 1 in that a step portion 202 between the central region 41 and the outer peripheral region 42 of the light-transmissive substrate 37, in other words, an inner peripheral side surface on the central region 41 side of the outer peripheral region 42 of the light-transmissive substrate 37 is formed in an arc shape inclined inward, and is common to the first embodiment in other points. In the step portion 202, a connection portion between the bottom surface of the central region 41 and the inner peripheral side surface of the outer peripheral region 42, which is an upper portion of the inner peripheral side surface in the cross-sectional view of FIG. 21, is formed in an arc shape.

As described above, by forming the upper portion of the inner peripheral side surface of the outer peripheral region 42 in an arc shape, it is possible to alleviate the stress applied to the step portion 202 and prevent breakage or cracks of the light-transmissive substrate 37. Further, it is possible to improve embeddability of the bonding resin 36 in the step portion 202 at the time of bonding the light-transmissive substrate 37.

<10. Fifth Embodiment of Solid-State Imaging Device>

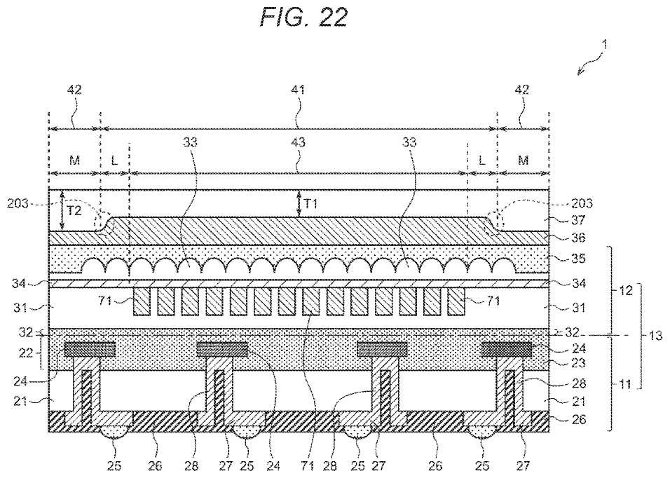

FIG. 22 is a cross-sectional view illustrating a configuration example of a fifth embodiment of a solid-state imaging device to which the present technology is applied.

In FIG. 22, portions corresponding to those of the first embodiment illustrated in FIG. 1 are denoted by the same reference numerals, and description of the portions will be omitted as appropriate.

The fifth embodiment in FIG. 22 is different from the first embodiment illustrated in FIG. 1 in that a step portion 203 between the central region 41 and the outer peripheral region 42 of the light-transmissive substrate 37, in other words, an inner peripheral side surface on the central region 41 side of the outer peripheral region 42 of the light-transmissive substrate 37 is formed in an arc shape inclined inward, and is common to the first embodiment in other points. In the cross-sectional view of FIG. 22, connection portions of both the upper portion and lower portion of the inner peripheral side surface of the step portion 203 are formed in an arc shape. The connection portion of the upper portion of the inner peripheral side surface is a connection portion between the bottom surface of the central region 41 and the inner peripheral side surface of the outer peripheral region 42, and the connection portion of the lower portion of the inner peripheral side surface is a connection portion between the inner peripheral side surface of the outer peripheral region 42 and the bottom surface.

As described above, by forming the upper portion and the lower portion of the inner peripheral side surface of the outer peripheral region 42 in an arc shape, it is possible to alleviate the stress applied to the step portion 203 and prevent breakage or cracks of the light-transmissive substrate 37. In addition, it is possible to improve embeddability of the bonding resin 36 in the step portion 203 at the time of bonding the light-transmissive substrate 37. Furthermore, the position of the inner peripheral side surface of the outer peripheral region 42 can be brought closer to the pixel region 43, and the chip strength can be further enhanced.

The shape of the light-transmissive substrate 37 of the second to fifth embodiments described above is not limited to the arrangement of the outer peripheral region 42 in which the outer peripheral region 42 surrounds the periphery of the central region 41 illustrated in FIG. 2, and can be similarly applied to the first and second shape examples illustrated in FIGS. 15 to 18.

<11. Configuration Example Including Color Filter Layer>

Although the color filter layer has not been described in each of the above-described embodiments, the solid-state imaging device 1 generally includes a color filter layer on the upper side of the photodiodes 71 formed in units of pixels.

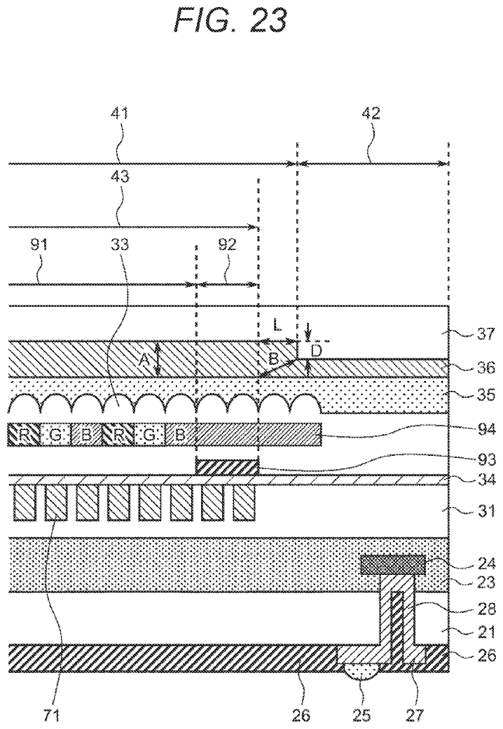

FIG. 23 is a cross-sectional view illustrating a configuration example in a case where the solid-state imaging device 1 includes a color filter layer.

Note that, similarly to FIG. 8, FIG. 23 illustrates a cross-sectional view of the vicinity of the end portion in a case where the OPB region 92 is provided.

In a case where the solid-state imaging device 1 includes the color filter layer, as illustrated in FIG. 23, the color filter layer 94 is formed between the on-chip lenses 33 and the light shielding film 93. In a case where the pixel region 43 does not include the OPB region 92 in which the light shielding film 93 is formed and includes only the effective pixel region 91, the color filter layer 94 is formed between the on-chip lenses 33 and the planarization film 34.

The color filter layer 94 is a layer that transmits light of a predetermined wavelength such as red (R), green (G), blue (B), and the like, and for example, as illustrated in FIG. 23, each color of R, G, and B is repeatedly disposed in order in units of pixels in each row of the pixel array section 52. Note that the arrangement of colors disposed in each pixel 51 of the color filter layer 94 is not limited to this example. For example, a Bayer array or a combination of R, G, B, W (white), and the like may be used. W is a layer that transmits light of all wavelengths.

Further, in accordance with the on-chip lenses 33 being formed to the outside of the pixel region 43 in order to prevent lens shape collapse at the end portion of the pixel region 43, the color filter layer 94 is also formed to the outside of the pixel region 43 in order to ensure continuity of the base. The color filter layer 94 outside the OPB region 92 and the pixel region 43 where light is not incident on the photodiodes 71 can have the same color. In the example of FIG. 23, the color is B, but other colors may be used.

In a case where the color filter layer 94 is disposed between the on-chip lenses 33 and the light shielding film 93, the material of the insulating layer on the lower side of the color filter layer 94 may be a material different from the material of the on-chip lenses 33 on the upper side of the color filter layer 94.

As described above, in the solid-state imaging device 1 which is the CSP-type solid-state imaging device having the cavityless structure, by forming the film thickness of the light-transmissive substrate 37 in the central region 41 corresponding to the pixel region 43 to be thin with respect to the outer peripheral region 42, it is possible to suppress the total thickness on the light incident surface side while increasing the strength of the chip, and thus, it is possible to suppress the adverse effect of the high-order light of the diffracted light in which the incident light is reflected on the surface of the upper substrate 12 on the image quality.

<12. Usage Example of Image Sensor>

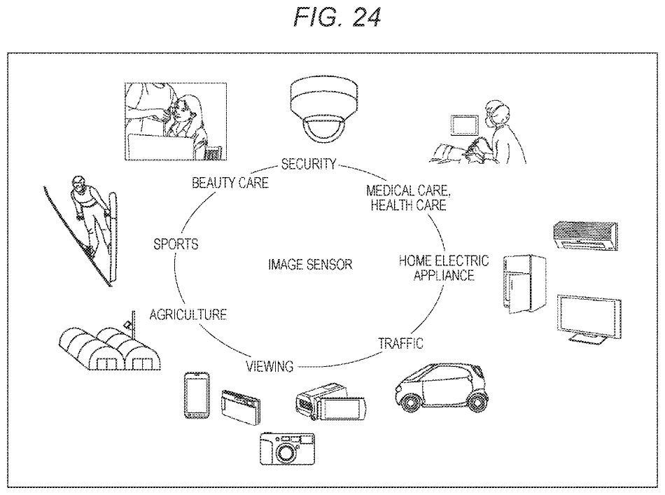

FIG. 24 is a diagram illustrating a usage example of an image sensor using the above-described solid-state imaging device 1.

The image sensor using the above-described solid-state imaging device 1 can be used, for example, in various cases of sensing light such as visible light, infrared light, ultraviolet light, X-rays, and the like as follows.
A device that captures an image to be used for viewing, such as a digital camera, a portable device with a camera function, or the like
A device used for traffic, such as an in-vehicle sensor that captures images of the front, rear, surroundings, inside, and the like of an automobile for safe driving such as automatic stop and the like, recognition of a driver's condition, and the like, a monitoring camera that monitors traveling vehicles and roads, and a distance measuring sensor that measures a distance between vehicles and the like.
A device used for home electric appliances such as a TV, a refrigerator, an air conditioner, and the like in order to capture an image of a gesture of a user and perform a device operation according to the gesture
A device used for medical care or health care, such as an endoscope, a device that performs angiography by receiving infrared light, and the like
A device used for security, such as a monitoring camera for crime prevention, a camera for person authentication, and the like
A device used for beauty care, such as a skin measuring instrument for photographing skin, a microscope for photographing scalp, and the like
A device used for sports, such as an action camera or a wearable camera for sports or the like
A device used for agriculture, such as a camera for monitoring conditions of fields and crops, and the like

<13. Application Example to Electronic Device>

The present technology is not limited to application to a solid-state imaging device. That is, the present technology can be applied to all electronic devices using a solid-state imaging device as an image capturing section (photoelectric conversion section), such as an imaging device such as a digital still camera, a video camera, or the like, a mobile terminal device having an imaging function, a copying machine using a solid-state imaging device as an image reading section, and the like. The solid-state imaging device may be formed as one chip, or may be in the form of a module having an imaging function in which an imaging section and a signal processing section or an optical system are packaged together.

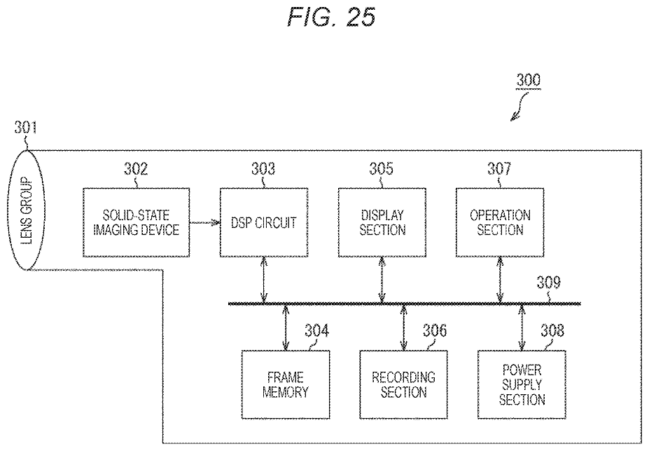

FIG. 25 is a block diagram illustrating a configuration example of an imaging device as an electronic device to which the present technology is applied.

An imaging device 300 in FIG. 25 includes an optical section 301 including a lens group and the like, a solid-state imaging device (imaging device) 302 in which the configuration of the solid-state imaging device 1 in FIG. 1 is adopted, and a digital signal processor (DSP) circuit 303 that is a camera signal processing circuit. Further, the imaging device 300 also includes a frame memory 304, a display section 305, a recording section 306, an operation section 307, and a power supply section 308. The DSP circuit 303, the frame memory 304, the display section 305, the recording section 306, the operation section 307, and the power supply section 308 are connected to one another via a bus line 309.

The optical section 301 captures incident light (image light) from a subject and forms an image on an imaging surface of the solid-state imaging device 302. The solid-state imaging device 302 converts the light amount of the incident light imaged on the imaging surface by the optical section 301 into an electrical signal in units of pixels and outputs the electrical signal as a pixel signal. As the solid-state imaging device 302, it is possible to use the solid-state imaging device 1 in FIG. 1, that is, a CSP-type solid-state imaging device having a cavityless structure in which the strength of the chip is increased and the adverse effect exerted on the image quality by the high-order light of the diffracted light in which the incident light is reflected on the surface of the upper substrate 12 is suppressed.

The display section 305 includes, for example, a thin display such as a liquid crystal display (LCD), an organic electro luminescence (EL) display, or the like, and displays a moving image or a still image captured by the solid-state imaging device 302. The recording section 306 records the moving image or the still image captured by the solid-state imaging device 302 on a recording medium such as a hard disk, a semiconductor memory, or the like.

The operation section 307 issues operation commands for various functions of the imaging device 300 under operation by the user. The power supply section 308 appropriately supplies various power sources serving as operation power sources of the DSP circuit 303, the frame memory 304, the display section 305, the recording section 306, and the operation section 307 to these supply targets.

As described above, by using the solid-state imaging device 1 to which each of the above-described embodiments is applied as the solid-state imaging device 302, it is possible to improve chip strength and image quality. Therefore, even in the imaging device 300 such as a video camera, a digital still camera, a camera module for a mobile device such as a mobile phone or the like, or the like, the image quality of the captured image can be improved.

<14. Application Example to Endoscopic Surgery System>

The technology according to an embodiment of the present disclosure (present technology) can be applied to various products. For example, the technology according to an embodiment of the present disclosure may be applied to an endoscopic surgery system.

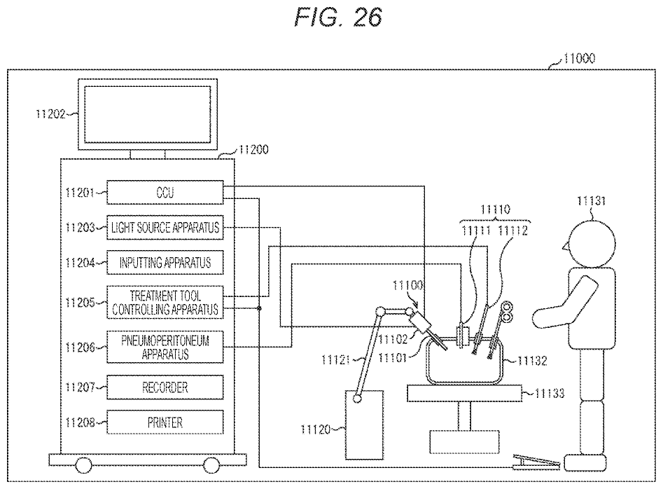

FIG. 26 is a view depicting an example of a schematic configuration of an endoscopic surgery system to which the technology according to an embodiment of the present disclosure (present technology) can be applied.

In FIG. 26, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

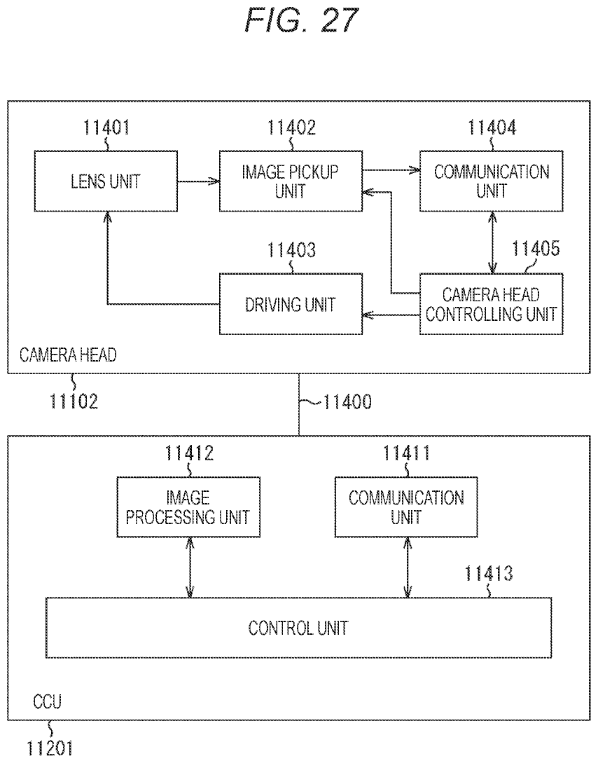

FIG. 27 is a block diagram depicting an example of a functional configuration of the camera head 11102 and the CCU 11201 depicted in FIG. 26.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to an embodiment of the present disclosure can be applied has been described above. The technology according to an embodiment of the present disclosure can be applied to the lens unit 11401 and the image pickup unit 11402 of the camera head 11102 among the above-described configurations. Specifically, the solid-state imaging device 1 according to each embodiment can be applied as the lens unit 11401 and the image pickup unit 11402. By applying the technology according to an embodiment of the present disclosure to the lens unit 11401 and the image pickup unit 11402, it is possible to obtain a clearer surgical region image while downsizing the camera head 11102.

Note that, here, the endoscopic surgery system has been described as an example, but the technology according to an embodiment of the present disclosure may be applied to, for example, a microscopic surgery system or the like.

<15. Application Example to Mobile Body>

The technology according to an embodiment of the present disclosure (present technology) can be applied to various products. For example, the technology according to an embodiment of the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

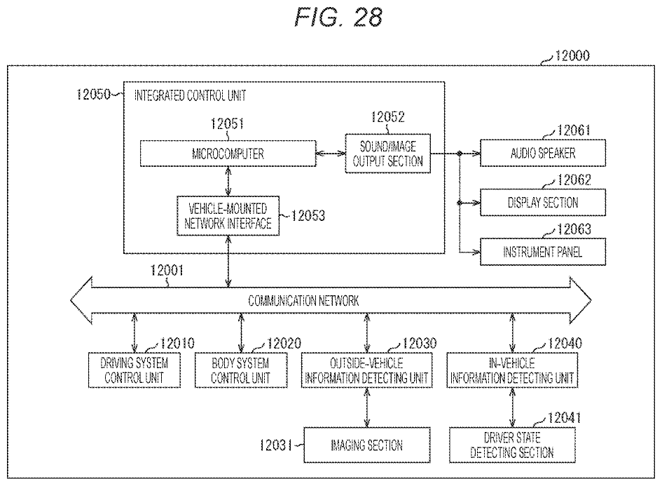

FIG. 28 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 28, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 28, an audio speaker 12061, a display section 12062, and an instrument panel 12063 are illustrated as the output device. The display section 12062 may, for example, include at least one of an on-board display and a head-up display.

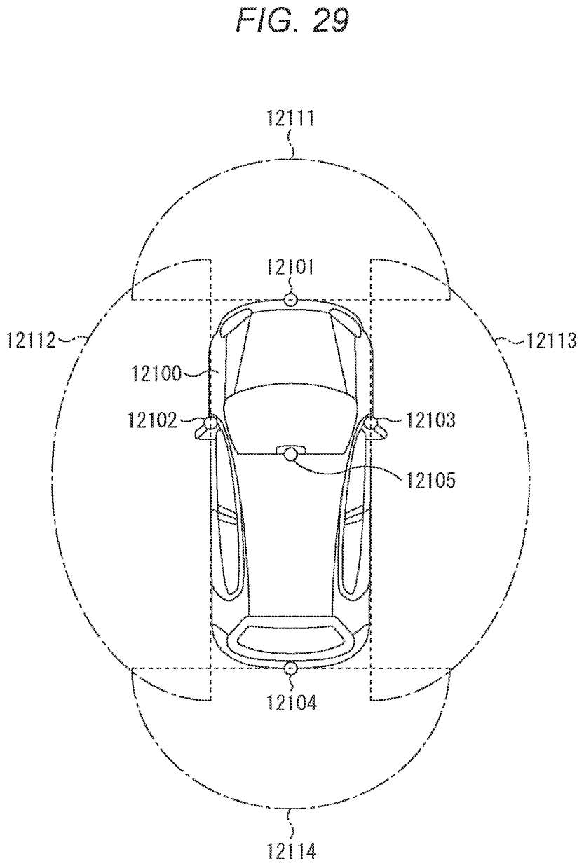

FIG. 29 is a diagram depicting an example of the installation position of the imaging section 12031.

In FIG. 29, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The front images acquired by the imaging sections 12101 and 12105 are mainly used for detecting a preceding vehicle, a pedestrian, an obstacle, a traffic light, a traffic sign, a lane, or the like.

Incidentally, FIG. 29 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied has been described above. The technology according to an embodiment of the present disclosure can be applied to the imaging section 12031 among the configurations described above. Specifically, the solid-state imaging device 1 according to each embodiment can be applied as the imaging section 12031. By applying the technology according to an embodiment of the present disclosure to the imaging section 12031, it is possible to obtain a more easily viewable captured image while reducing the size. In addition, it is possible to reduce driver's fatigue and increase the safety of the driver and the vehicle by using the obtained captured image.

Further, the present technology is not limited to application to a solid-state imaging device that detects distribution of the amount of incident light of visible light and captures the distribution as an image, and can be applied to all solid-state imaging devices (physical quantity distribution detection devices) such as a solid-state imaging device that captures distribution of the amount of incident infrared rays, X-rays, particles, or the like as an image, a fingerprint detection sensor that detects distribution of other physical quantities such as pressure, capacitance, and the like, and captures the distribution as an image in a broad sense, and the like.

Further, the present technology can be applied not only to solid-state imaging devices but also to general semiconductor devices having other semiconductor integrated circuits.

The embodiments of the present technology are not limited to the above-described embodiments, and various modifications can be made without departing from the gist of the present technology.

For example, a form in which all or some of the plurality of embodiments described above are combined can be adopted.

Note that the effects described in the present specification are merely examples and are not limited, and effects other than those described in the present specification may be provided.

Note that the present technology can have the following configurations.

(1)

A solid-state imaging device including:

a semiconductor substrate in which a photoelectric conversion section is formed for a pixel;

an on-chip lens formed on a light incident surface side of the semiconductor substrate;

a light-transmissive substrate that protects the on-chip lens; and

a bonding resin that bonds the light-transmissive substrate and the on-chip lens together,

in which a first surface on a light incident surface side of the light-transmissive substrate is flat, and

a second surface opposite to the first surface of the light-transmissive substrate has different thicknesses in a central region facing a pixel region of the semiconductor substrate and an outer peripheral region outside the central region.

(2)

The solid-state imaging device according to (1),

in which a thickness of the central region of the light-transmissive substrate is formed to be smaller than a thickness of the outer peripheral region.

(3)

The solid-state imaging device according to (1) or (2),

in which the bonding resin has different thicknesses in the central region and the outer peripheral region.

(4)

The solid-state imaging device according to (3),

in which a thickness of the central region of the bonding resin is formed to be thicker than a thickness of the outer peripheral region.

(5)

The solid-state imaging device according to any one of (1) to (4),

in which the central region is a region expanded outward from the pixel region by a predetermined width L (>0) in plan view.

(6)

The solid-state imaging device according to (5),

in which a distance between an end portion of the pixel region and a corner portion of the outer peripheral region inside a bottom surface of the light-transmissive substrate is the predetermined width L.

(7)

The solid-state imaging device according to (5) or (6),

in which when a difference between a thickness of the central region and a thickness of the outer peripheral region of the light-transmissive substrate is denoted by D, and a thickness of the bonding resin in the central region is denoted by A,

a minimum value of the predetermined width L is

L=\sqrt{2AD−D²} [Mathematical formula 3]

(8)

The solid-state imaging device according to any one of (1) to (7),

in which the pixel region includes an effective pixel region and an OPB region.

(9)

The solid-state imaging device according to any one of (1) to (8),

in which a planar shape of the outer peripheral region of the light-transmissive substrate is a rectangular shape.

(10)

The solid-state imaging device according to any one of (1) to (8),

in which a planar shape of the outer peripheral region of the light-transmissive substrate is a line shape along two sides of a rectangle in either a left-right direction or an up-down direction.

(11)

The solid-state imaging device according to any one of (1) to (8),

in which a planar shape of the outer peripheral region of the light-transmissive substrate is a shape in which an L shape is disposed at each corner portion of a rectangle.

(12)

The solid-state imaging device according to any one of (1) to (8),

in which the light-transmissive substrate has a recess in at least one direction of up-down and left-right directions of the outer peripheral region having a rectangular shape formed to be thicker than the central region.

(13)

The solid-state imaging device according to any one of (1) to (12), further including

an interlayer insulating film on the on-chip lens,

in which the bonding resin bonds the light-transmissive substrate and the interlayer insulating film together.

(14)

The solid-state imaging device according to any one of (1) to (12),

in which the bonding resin bonds the light-transmissive substrate and the on-chip lens together.

(15)

The solid-state imaging device according to any one of (1) to (14),

in which an inner peripheral side surface of the outer peripheral region of the light-transmissive substrate on a side of the central region is formed in a tapered shape.

(16)

The solid-state imaging device according to any one of (1) to (14),

in which an upper portion of an inner peripheral side surface of the outer peripheral region of the light-transmissive substrate on a side of the central region is formed in an arc shape.

(17)

The solid-state imaging device according to any one of (1) to (14),

in which an upper portion and a lower portion of an inner peripheral side surface of the outer peripheral region of the light-transmissive substrate on a side of the central region are formed in arc shapes.

(18)

A method of manufacturing a solid-state imaging device, the solid-state imaging device including:

a semiconductor substrate in which a photoelectric conversion section is formed for a pixel;

an on-chip lens formed on a light incident surface side of the semiconductor substrate; and

a light-transmissive substrate that protects the on-chip lens,

in which a first surface on a light incident surface side of the light-transmissive substrate is flat,

a second surface opposite to the first surface of the light-transmissive substrate has different thicknesses in a central region facing a pixel region of the semiconductor substrate and an outer peripheral region outside the central region, and

the light-transmissive substrate and the on-chip lens are bonded together with a bonding resin.

(19)

The method of manufacturing the solid-state imaging device according to (18),

in which the light-transmissive substrate in a wafer state in which the central region of each chip region is formed to be thinner than the outer peripheral region is bonded to an upper side of the on-chip lens with the bonding resin, and then divided in units of chips.

(20)

An electronic device including

a solid-state imaging device including:

a semiconductor substrate in which a photoelectric conversion section is formed for a pixel;

an on-chip lens formed on a light incident surface side of the semiconductor substrate;

a light-transmissive substrate that protects the on-chip lens; and

a bonding resin that bonds the light-transmissive substrate and the on-chip lens together,

in which a first surface on a light incident surface side of the light-transmissive substrate is flat, and

a second surface opposite to the first surface of the light-transmissive substrate has different thicknesses in a central region facing a pixel region of the semiconductor substrate and an outer peripheral region outside the central region.

### REFERENCE SIGNS LIST

1 Solid-state imaging device
11 Lower substrate
12 Upper substrate
13 Laminated substrate
21 Semiconductor substrate (silicon substrate)
24 Internal electrode
25 Solder bump
27 Rewiring line
31 Semiconductor substrate (silicon substrate)
32 Wiring layer
33 On-chip lens
35 Interlayer insulating film
36 Bonding resin
37 Light-transmissive substrate
41 Central region
42 Outer peripheral region
43 Pixel region
51 Pixel
71 Photodiode
91 Effective pixel region
92 OPB region
93 Light shielding film
94 Color filter layer
201, 202, 203 Step portion
300 Imaging device
302 Solid-state imaging device

1. A solid-state imaging device comprising:
a semiconductor substrate in which a photoelectric conversion section is formed for a pixel;
an on-chip lens formed on a light incident surface side of the semiconductor substrate;
a light-transmissive substrate that protects the on-chip lens; and
a bonding resin that bonds the light-transmissive substrate and the on-chip lens together,
wherein a first surface on a light incident surface side of the light-transmissive substrate is flat, and
a second surface opposite to the first surface of the light-transmissive substrate has different thicknesses in a central region facing a pixel region of the semiconductor substrate and an outer peripheral region outside the central region.

2. The solid-state imaging device according to claim 1,
wherein a thickness of the central region of the light-transmissive substrate is formed to be smaller than a thickness of the outer peripheral region.

3. The solid-state imaging device according to claim 1,
wherein the bonding resin has different thicknesses in the central region and the outer peripheral region.

4. The solid-state imaging device according to claim 3,
wherein a thickness of the central region of the bonding resin is formed to be thicker than a thickness of the outer peripheral region.

5. The solid-state imaging device according to claim 1,
wherein the central region is a region expanded outward from the pixel region by a predetermined width L (>0) in plan view.

6. The solid-state imaging device according to claim 5,
wherein a distance between an end portion of the pixel region and a corner portion of the outer peripheral region inside a bottom surface of the light-transmissive substrate is the predetermined width L.

7. The solid-state imaging device according to claim 5,
wherein when a difference between a thickness of the central region and a thickness of the outer peripheral region of the light-transmissive substrate is denoted by D, and a thickness of the bonding resin in the central region is denoted by A,
a minimum value of the predetermined width L is
L=\sqrt{2AD−D²}. [Mathematical formula 1]

8. The solid-state imaging device according to claim 1,
wherein the pixel region includes an effective pixel region and an OPB region.

9. The solid-state imaging device according to claim 1,
wherein a planar shape of the outer peripheral region of the light-transmissive substrate is a rectangular shape.

10. The solid-state imaging device according to claim 1,
wherein a planar shape of the outer peripheral region of the light-transmissive substrate is a line shape along two sides of a rectangle in either a left-right direction or an up-down direction.

11. The solid-state imaging device according to claim 1,
wherein a planar shape of the outer peripheral region of the light-transmissive substrate is a shape in which an L shape is disposed at each corner portion of a rectangle.

12. The solid-state imaging device according to claim 1,
wherein the light-transmissive substrate has a recess in at least one direction of up-down and left-right directions of the outer peripheral region having a rectangular shape formed to be thicker than the central region.

13. The solid-state imaging device according to claim 1, further comprising:
an interlayer insulating film on the on-chip lens,
wherein the bonding resin bonds the light-transmissive substrate and the interlayer insulating film together.

14. The solid-state imaging device according to claim 1,
wherein the bonding resin bonds the light-transmissive substrate and the on-chip lens together.

15. The solid-state imaging device according to claim 1,
wherein an inner peripheral side surface of the outer peripheral region of the light-transmissive substrate on a side of the central region is formed in a tapered shape.

16. The solid-state imaging device according to claim 1,
wherein an upper portion of an inner peripheral side surface of the outer peripheral region of the light-transmissive substrate on a side of the central region is formed in an arc shape.

17. The solid-state imaging device according to claim 1,
wherein an upper portion and a lower portion of an inner peripheral side surface of the outer peripheral region of the light-transmissive substrate on a side of the central region are formed in arc shapes.

18. A method of manufacturing a solid-state imaging device, the solid-state imaging device comprising:
a semiconductor substrate in which a photoelectric conversion section is formed for a pixel;
an on-chip lens formed on a light incident surface side of the semiconductor substrate; and
a light-transmissive substrate that protects the on-chip lens,
wherein a first surface on a light incident surface side of the light-transmissive substrate is flat,
a second surface opposite to the first surface of the light-transmissive substrate has different thicknesses in a central region facing a pixel region of the semiconductor substrate and an outer peripheral region outside the central region, and
the light-transmissive substrate and the on-chip lens are bonded together with a bonding resin.

19. The method of manufacturing the solid-state imaging device according to claim 18,
wherein the light-transmissive substrate in a wafer state in which the central region of each chip region is formed to be thinner than the outer peripheral region is bonded to an upper side of the on-chip lens with the bonding resin, and then divided in units of chips.

20. An electronic device comprising:
a solid-state imaging device including:
a semiconductor substrate in which a photoelectric conversion section is formed for a pixel;
an on-chip lens formed on a light incident surface side of the semiconductor substrate;
a light-transmissive substrate that protects the on-chip lens; and
a bonding resin that bonds the light-transmissive substrate and the on-chip lens together,
wherein a first surface on a light incident surface side of the light-transmissive substrate is flat, and
a second surface opposite to the first surface of the light-transmissive substrate has different thicknesses in a central region facing a pixel region of the semiconductor substrate and an outer peripheral region outside the central region.
